(19) United States
(12) Patent Application Publication
(10) Pub. No.: US 2004/0127014 A1
(43) Pub. Date: Jul. 1, 2004

(54) Method of improving a barrier layer in a via or contact opening

(76) Inventors: Cheng-Lin Huang, Taipei (TW); Ching-Hua Hsieh, Hsinchu (TW); Shau-Lin Shue, Hsinchu (TW)

Correspondence Address: SLATER & MATSIL, L.L.P., 17950 PRESTON RD, SUITE 1000, DALLAS, TX, 75252-5793, US

(21) Appl. No.: 10/334,197

(22) Filed: Dec. 30, 2002

(51) Int. Cl. H01L 21/4763

(52) U.S. Cl. 438/627

(57) ABSTRACT

A tunable process for forming a barrier layer in an opening is provided. First, a dielectric layer is formed on a substrate. Second, an opening is formed in the dielectric layer. The opening has sidewalls and a bottom. Third, barrier layer material is deposited on the sidewalls and bottom of the opening. Fourth, sputter etching is used to remove barrier layer material from an overhang portion of the barrier layer and to redistribute barrier layer material removed from the overhang portion to the sidewalls. During the sputter etching step, the sputter etching may also remove barrier layer material from the bottom of the opening and redistributes barrier layer material removed from the bottom of the opening to the sidewalls. The sputter etching parameters may be selected to achieve a desired barrier layer configuration.

### TECHNICAL FIELD

The present invention relates to semiconductor manufacturing processes. In one aspect, it relates to the formation of a barrier layer in a contact opening and/or in a via.

### BACKGROUND

When depositing a barrier layer 18 into a contact opening (e.g., contact trench, via, and/or contact hole), such as the opening 20 shown in FIG. 1, the barrier layer 18 often does not have a uniform thickness at all areas along the interior surface of the opening 20. FIG. 2 shows a typical barrier layer 18 formed from tantalum nitride (TaN), for example. Due to the inconsistent barrier layer thicknesses, there are a number problems.

The barrier layer 18 is typically deposited by physical vapor deposition, for example. Alternatively, the barrier layer 18 may be deposited by chemical vapor deposition or atomic layer deposition.

The deposition process may result in several undesirable features in the resulting barrier layer. Overhang portions 22 that develop on the outward facing corners 24 create a shadow effect for the inward facing comers 26 below the overhang portions 22. Due to the overhangs 22, when contact metal (not shown) (e.g., tungsten or copper) is deposited inside the contact opening 20, microvoids often form at the inward facing comers 26. Also, during the formation of the barrier layer 18, the overhang portions 22 block or hinder the formation of barrier layer sidewalls 28 at the inward facing corners 26, which causes thin barrier layer sidewalls at localized regions 30 of these comers 26. Such thin sidewall portions 30 are undesirable and may allow migration of copper into the adjacent dielectric layer 32, which may degrade device performance. To make the sidewall portions 30 thick enough at the inward facing corners 26 using conventional methods, more barrier layer material would need to be applied, which further compounds the overhang problems. Also, the application of more barrier layer material results in a thicker portion 34 at the via bottom, which is also undesirable. A thicker barrier layer portion 34 at the via bottom causes greater contact resistance at the via bottom. It is highly desirable to obtain a minimum contact resistance at the via bottom portion 34, but while still providing sufficient barrier layer coverage to prevent migration of the via-filling metal into the underlying doped silicon regions and substrate 36. Hence, there is a need for a way to provide an improved barrier layer.

### BRIEF SUMMARY OF THE INVENTION

The problems and needs outlined above are addressed by embodiments of the present invention. In accordance with one aspect of the present invention, a method of forming a barrier layer in an opening is provided. The method includes the following steps (the order of which may vary). A dielectric layer is formed on a substrate. An opening is formed in the dielectric layer. The opening has sidewalls and a bottom. Barrier layer material is deposited on the sidewalls and bottom of the opening. Sputter etching is used to remove barrier layer material from an overhang portion of the barrier layer and to redistribute barrier layer material removed from the overhang portion to the sidewalls.

During the sputter etching, it also may be used to remove barrier layer material from the bottom of the opening and to redistribute barrier layer material removed from the bottom of the opening to the sidewalls. Preferably, the barrier layer is thicker along the sidewalls than along the bottom after the sputter etching step. For example, the barrier layer along the sidewalls may have a sidewall thickness of about 50 Å after the sputter etching step, and the barrier layer along the bottom may have a bottom thickness ranging from 0 to about 150 Å after the sputter etching step. Preferably, the barrier layer along the sidewalls has substantially uniform thickness after the sputter etching step. The sputter etching step may include bombarding select portions of the barrier layer with particles of an inert gas, such as argon. The source power for the inert gas sputter etching may be in a range of about 100 watts to about 3000 watts, and the bias power for the inert gas sputter etching may be in a range of about 100 watts to about 2000 watts, for example. The method may be used in a method of manufacturing a semiconductor device.

In accordance with another aspect of the present invention, a method of forming a barrier layer in an opening is provided. This method includes the following steps (the order of which may vary). A dielectric layer is formed on a substrate. An opening is formed in the dielectric layer, the opening having sidewalls and a bottom. Barrier layer material is deposited on the sidewalls and bottom of the opening. Sputter etching is used to remove barrier layer material from the bottom of the opening and to redistribute barrier layer material removed from the bottom of the opening to the sidewalls.

In accordance with still another aspect of the present invention, a tunable process for redistributing portions of a barrier layer in an opening is provided. The tunable process includes the following steps (the order of which may vary). A dielectric layer is formed on a substrate. An opening is formed in the dielectric layer. The opening has sidewalls and a bottom. A barrier layer material is deposited on the sidewalls and bottom of the opening. At least one sputter process parameter is selected for obtaining a desired barrier layer configuration. The barrier layer material is sputter etched in accordance with the selected parameter(s) to redistribute portions of the barrier layer material and to provide the desired barrier layer configuration.

In a tunable process, the selected parameter(s) may include at least one of a sputtering time, a sputtering power, a sputtering source material, and a sputtering gas, for example. As a specific example, the selected parameter may be a sputtering time that ranges from about 2 seconds to about 24 seconds. In another specific example, the selected parameter may be a sputtering power for a source power ranging from about 100 watts to about 3000 watts and/or for a bias power ranging from about 100 watts to about 2000 watts.

In accordance with yet another aspect of the present invention, a method of forming an interconnect between layers for a semiconductor device is provided. This method includes the following steps (the order of which may vary). An opening is formed in one or more dielectric layers, wherein the opening opens to an underlying layer that is beneath the one or more dielectric layers. Barrier layer material is deposited on interior surfaces of the opening to form a barrier layer. Sputter etching is used to remove barrier layer material from overhang portions of the barrier layer, to redistribute barrier layer material removed from the overhang portions to sidewalls of the opening, to remove barrier layer material from a bottom of the opening, and to redistribute barrier layer material removed from the bottom of the opening to the sidewalls, wherein the barrier layer is thicker along the sidewalls than along the bottom after the sputter etching step. A conductive material is deposited into the opening.

In accordance with still another aspect of the present invention, a semiconductor device is provided, which includes: a first layer, an opening, a barrier layer, and a conductive material. The first layer is formed over an underlying layer. The opening is formed in the first layer and opening to the underlying layer. The barrier layer is formed within the opening, wherein the barrier layer is thicker along sidewalls of the opening than along a bottom of the opening. A conductive material is formed on the barrier layer and within the opening.

The opening may open to a doped silicon region, such as a source or drain, or to a gate electrode that is beneath the first layer. Also, the opening may open to a conductive material portion within the underlying layer. The conductive material portion may be a metal connecting line. The barrier layer may have a substantially uniform thickness along the sidewalls of the opening. The barrier layer along the sidewalls may have a sidewall thickness of about 50 Å, and the barrier layer along the bottom may have a bottom thickness ranging from 0 to about 150 Å. The first layer may include two dielectric layers.

### BRIEF DESCRIPTION OF THE DRAWINGS

The above features of the present invention will be more clearly understood from consideration of the following descriptions in connection with accompanying drawings in which:

FIG. 1 is a cross-section side view of a substrate having dielectric layers with an opening formed thereon;

FIG. 2 shows the opening of FIG. 1 having a barrier layer formed therein;

FIG. 3 illustrates a sputter etching step to redistribute portions of the barrier layer of FIG. 2;

FIG. 4 shows a resulting barrier layer after the sputter etching step;

FIG. 5 is a cross-section side view of a metal connection layer having a dielectric layer with an opening formed thereon;

FIG. 6 shows the opening of FIG. 5 having a barrier layer formed therein;

FIG. 7 illustrates a sputter etching step to redistribute portions of the barrier layer of FIG. 6;

FIG. 8 shows a resulting barrier layer after the sputter etching step;

FIG. 9 shows a resulting barrier layer after the sputter etching step where the via-bottom portion of the barrier layer has punched through to the conductive layer therebelow; and

FIG. 10 shows the opening of FIG. 9 having the opening filled with a conductive material.

### DETAILED DESCRIPTION OF PREFERRED EMBODIMENTS

Referring now to the drawings, wherein like reference numbers are used herein to designate like elements throughout the various views, preferred embodiments of the present invention are illustrated and described. As will be understood by one of ordinary skill in the art, the figures are not necessarily drawn to scale, and in some instances the drawings have been exaggerated and/or simplified in places for illustrative purposes only. One of ordinary skill in the art will appreciate the many applications and variations of the present invention in light of the following description for preferred embodiments of the present invention. The preferred embodiments discussed herein are just a few illustrative examples of the present invention and do not necessarily limit the scope of the invention to the preferred embodiments described.

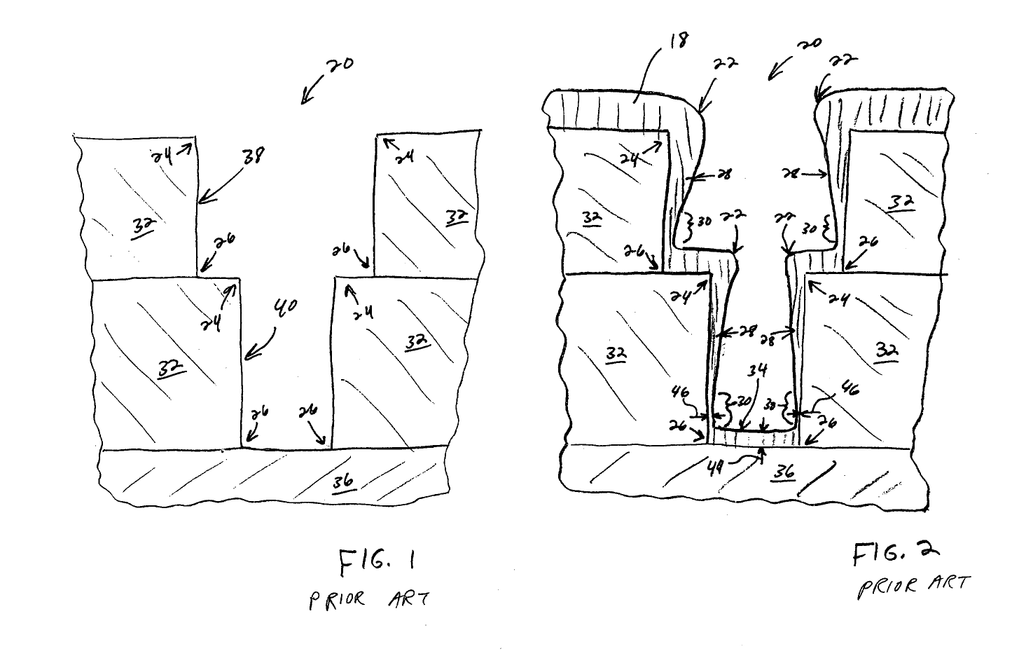

FIG. 1 is a cross-section side view of a substrate 36 having dielectric layers 32 formed thereon. The dielectric layers 32 have an opening 20 formed therein. The upper portion 38 of the opening 20 may be a trench projecting into the page for a metal interconnect line, for example. The lower portion 40 of the opening 20 may be a generally cylindrical-shaped via hole formed in the lower dielectric layer 32. Other opening shapes, such as rectangular, are also within the scope of the present invention. The opening 20 may be formed as part of a double damascene process, for example, although single damascene processes are also contemplated. After the barrier layer 18 is formed in the opening 20, the opening 20 will be filled with a conducting material (not shown), such as copper. Copper (as well as many other conductors) requires the barrier layer 18 to prevent the copper from penetrating into and through adjacent dielectric layers 32, doped silicon, and/or silicon substrate materials 36. Additionally, the barrier layer 18 may provide for improved adhesion between the dielectric layers 32 and the conducting material (not shown) that will fill the opening 20. For example, copper does not adhere well to many dielectric layers, such as silicon dioxide. In some embodiments, an additional layer, such as tantalum nitride, may be formed before or after the formation of a tantalum layer to promote improved barrier properties and/or improved adhesion properties.

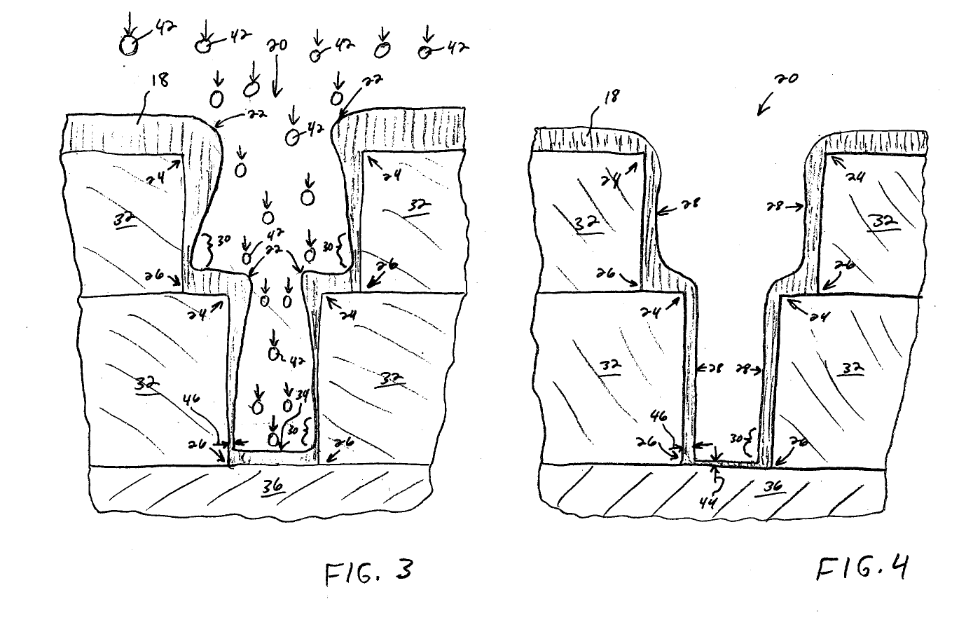

As discussed above, there are many undesirable features resulting in a conventional barrier layer 18 (see e.g., FIG. 2): thin sidewall portions 30, overhang portions 22, and a thick via-bottom portion 34. To address the problems associated with these undesirable features, an embodiment of the present invention may be used as a process to remove and/or redistribute select portions of the barrier layer 18 to form more desirable barrier layer features. In a manufacturing process in accordance with a preferred embodiment of the present invention, portions of the barrier layer 18 are removed and/or redistributed using an anisotropic noble gas or inert gas sputter directed toward the bottom of the opening 20, as shown in FIG. 3.

The sputter etching step shown in FIG. 3 results in the barrier layer 18 shown in FIG. 4, for example. Note that in FIG. 4, the overhang portions 22 (shown in FIG. 3) have been substantially reduced. The sidewalls 28 have become thicker at the thin portions 30 (compare FIG. 4 to FIG. 3) and more uniform in thickness. And, the via-bottom portion 34 of the barrier layer 18 has become thinner. These are all highly desirable results. When the structure shown in FIG. 4 is next filled with a conducting metal (not shown), such as copper for example, there will be less likelihood of microvoid formation at the bottom comers 26, better coverage at the bottom corners 26 due to the removal of the overhang portions 22 (see FIG. 3), and the improved thickness uniformity of the sidewalls 28 (see FIG. 4). Note that the resulting barrier layer 18 in FIG. 4 may have substantially vertical sidewalls 28 at the lower portion 40 of the opening 20 unobstructed by overhang portions 22 because the overhang portions 22 and the via-bottom portion 34 of the barrier layer 18 have been redistributed.

During the sputter etching step using a noble gas or some other inert gas compound, because the gas is inert, the etching caused by the accelerated gas particles 42 is a physical etching process (see FIG. 3). The inert gas may be accelerated in a direction orthogonal to a surface plane of the wafer. However, the anisotropic sputter direction may be in any direction relative to the wafer (e.g., slanted). When the accelerated gas particles 42 strike the horizontal surfaces (i.e., surfaces generally parallel with the surface plane of the wafer) of the barrier layer 18, portions of the barrier layer material are sputtered off of the barrier layer 18 in an anisotropic manner. The liberated barrier layer material then sticks to and bonds with the adjacent sidewalls 28 (vertical portions) proximate to the impact locations of the accelerated gas particles 42. Hence, the barrier layer material is redistributed. In other embodiments, a non-inert gas may be used as the sputtering particle source. In the preferred embodiments, the anisotropic etching and redistribution of the barrier layer material results from primarily, if not exclusively, physical sputtering processes.

The amount of redistribution and the resulting barrier layer structure provided by the sputtering step provides consistent and repeatable results. By altering the variables involved in the sputtering step (i.e., sputter time, sputter power), a tunable barrier layer redistribution process is provided. Hence, the thickness of the via-bottom portion 34 of the barrier layer 18 may be reliably controlled using the tunable barrier layer redistribution process. Therefore, the process of the preferred embodiment provides a repeatable and consistent way of redistributing portions of the barrier layer 18 to form more desirable barrier layer features.

The following example will illustrate a use of the sputter etching process of a preferred embodiment to alter a barrier layer structure 18. Referring to FIG. 1, an opening 20 is formed in layers of silicon dioxide 32 using conventional processes as part of a dual damascene process. A film of tantalum nitride (TaN) is deposited over and into the opening 20 using conventional deposition processes to form a barrier layer 18 within the opening 20, as shown in FIG. 2. For example, the TaN film may be deposited using a physical vapor deposition process under a pressure of about 2-20 mTorr and using about 1-40 kW of power. The resulting barrier layer structure 18 is shown in FIG. 2. The thickness 44 of the via-bottom portion 34 before or without the sputter etching step typically may be about 150-250 nm, for example. The sidewall thickness 46 of the portion 30 near the via bottom corners 26 typically may be as thin as 20-30 Å.

Next, an argon sputtering step is performed, as shown in FIG. 3. The argon 42 is ionized and projected toward the via bottom 34 in one direction, and hence the physical etching by the argon 42 is anisotropic. The sputter time may vary between about 2-24 seconds, depending on the power levels used for the sputter and depending on the via-bottom layer thickness 44 desired for the barrier layer 18 (i.e., the bottom layer thickness 44 is tunable). A conventional coil (not shown) may be used to ionize the argon 42, and it may be turned on or turned off, as needed. The source power may be about 2 kW, and the bias power may be about 500-1000 W, for example. The resulting via-bottom portion thickness 44 is preferably about 20-50 Å after sputtering (see FIG. 4), but this thickness 44 can be more or less by varying the sputter time and/or varying the power values used for the sputtering process (i.e., tunable bottom layer thickness). With a via-bottom portion thickness 44 of about 20-50 Å, the sidewall thickness 46 near the via bottom corners 26 typically will be about 50 Å, and the overall sidewall thickness will be mostly uniform, as shown in FIG. 4. Therefore, the resulting sidewall thickness 46 is greater than the resulting via-bottom thickness 44 of the via-bottom portion 34 of the barrier layer 18.

Although argon is used in this example, other noble gases and/or other inert gas compounds may be used, including but not limited to: helium, neon, krypton, xenon, radon, or any combination thereof, for example. Also, tantalum ions or tantalum may be used a sputter source. In the example above, a TaN barrier layer is used; however, any barrier layer material may be used, including but not limited the following commonly used barrier layer materials: tantalum, tantalum alloys, titanium, titanium nitride, titanium alloys, TiZr, or any combination thereof, for example. Also, the material used to fill the via may be any conducting material, including but not limited to the following commonly used conductors: copper, copper alloys, aluminum, aluminum alloys, gold, silver, tungsten, tungsten alloys, platinum, nickel alloys, doped polysilicon, doped copper (e.g., doped with Mg, Sn, Zr, Ag, and/or In), or any combination thereof, for example. The dielectric layer may be any commonly used material used for such layers, including but not limited silicon dioxide, silicon nitride, silicon oxynitride, low-K dielectrics, spun glass dielectrics (e.g., FSG, USG).

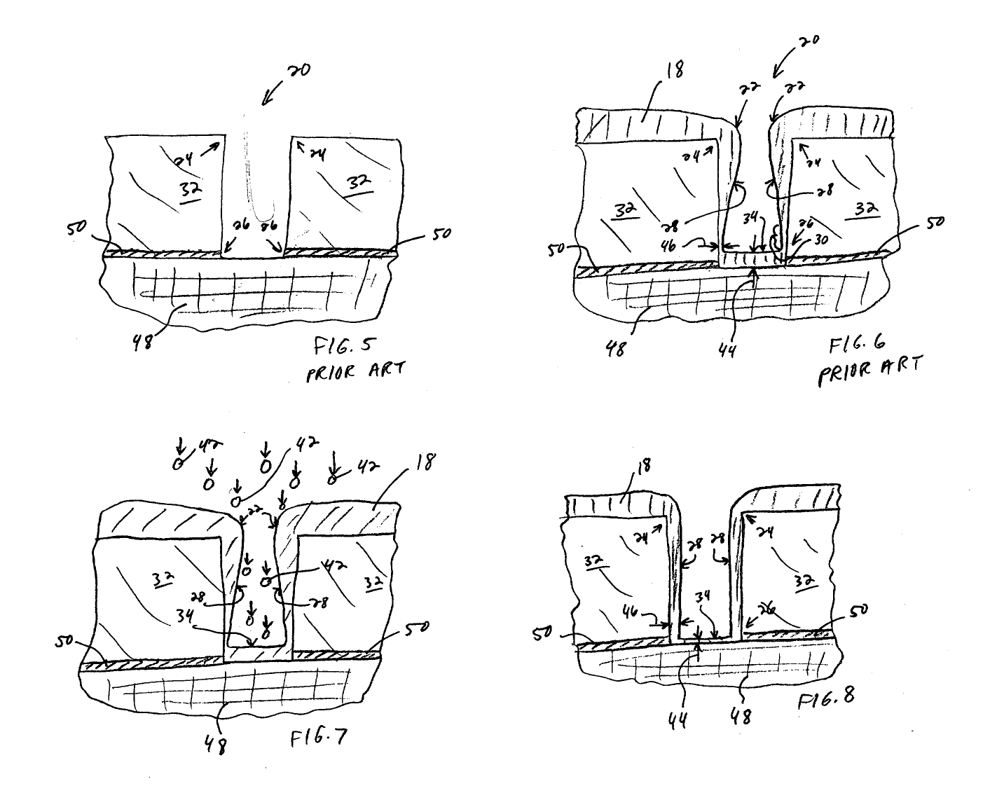

FIGS. 5-10 illustrate another example use of the preferred embodiment, as well as two options for the resulting via-bottom portion 34 of the barrier layer 18 to illustrate a use of the tunable bottom layer thickness option of the process. FIG. 5 shows a dielectric layer 32 formed on a connecting conductor layer 48, which may be a trench filled with conductive material formed in another dielectric layer (not shown in this view). There is likely to be a barrier layer 50 between the connection conductor layer 48 and the dielectric layer 32, as shown in FIG. 5, to prevent a metal line (e.g., copper, aluminum) in the connection conductor layer 48 from penetrating into or through the dielectric layer 32. The dielectric layer 32 has an opening 20 formed therein, which in this case is a via.

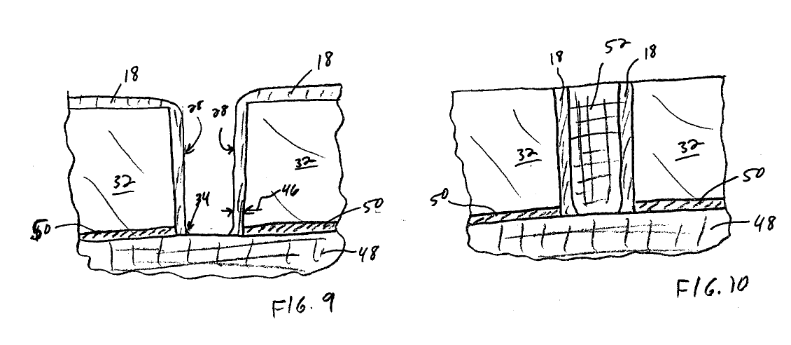

FIG. 6 shows the opening 20 of FIG. 5 with a barrier layer 18 formed therein using a conventional method of forming the barrier layer 18. FIG. 7 illustrates a step of sputter etching with an inert gas 42, for example, in an anisotropic manner (as described above regarding FIG. 3) to redistribute select portions of the barrier layer 18, namely the via-bottom portion 34 and the overhang portions 22. FIG. 8 illustrates a resulting barrier layer structure 18 where the overhang portions 22 have been reduced and the via-bottom portion thickness 44 has been reduced (e.g., 0-80 Å thick). Because the sputtering process is tunable, many different via-bottom portion thicknesses 44 are possible, as desired, based on the sputtering time and sputtering power. Because in this example the opening 20 opens to conducting material 48, it is desirable to punch through the barrier layer 18 at the via-bottom portion 34 to eliminate barrier layer resistance at this region, as shown in FIG. 9 (i.e., via-bottom portion thickness 44 equals zero). Further decreasing the via-bottom portion thickness 44 or punching through the via-bottom portion 34 may be done by simply increasing the sputtering time and/or increasing the sputtering power to further eroded away the via-bottom portion 34 with the sputter etching (see FIG. 7). Likewise, the resulting via-bottom portion 34 of the barrier layer 18 may be thicker than the resulting via-bottom portion of FIG. 8 by reducing the sputter time and/or reducing or changing the sputtering power. FIG. 10 shows the opening 20 of FIG. 9 after being filled with a conducting material 52 (e.g., copper) and having the excess material 52 and the top layer of the barrier layer 18 removed (e.g., by CMP). Thus, an improved metal-to-metal contact (e.g., Cu to Cu direct contact) in a via, or conductor-on-conductor interface at the bottom of the opening, may be formed using an embodiment of the present invention.

It will be appreciated by those skilled in the art having the benefit of this disclosure that an embodiment of the present invention provides a method for making an improved barrier layer in a via or contact opening. It should be understood that the drawings and detailed description herein are to be regarded in an illustrative rather than a restrictive manner, and are not intended to limit the invention to the particular forms and examples disclosed. On the contrary, the invention includes any further modifications, changes, rearrangements, substitutions, alternatives, design choices, and embodiments apparent to those of ordinary skill in the art, without departing from the spirit and scope of this invention, as defined by the following claims. Thus, it is intended that the following claims be interpreted to embrace all such further modifications, changes, rearrangements, substitutions, alternatives, design choices, and embodiments.

What is claimed is:

1. A method of forming a barrier layer in an opening, comprising:
forming a dielectric layer on a substrate;
forming an opening in the dielectric layer, the opening having sidewalls and a bottom;
depositing barrier layer material on the sidewalls and bottom of the opening; and
sputter etching to remove barrier layer material from an overhang portion of the barrier layer and to redistribute barrier layer material removed from the overhang portion to the sidewalls.

2. The method of claim 1, wherein during the sputter etching step, the sputter etching also removes barrier layer material from the bottom of the opening and redistributes barrier layer material removed from the bottom of the opening to the sidewalls.

3. The method of claim 2, wherein the barrier layer is thicker along the sidewalls than along the bottom after the sputter etching step.

4. The method of claim 3, wherein the barrier layer along the sidewalls has a sidewall thickness of about 50 Å after the sputter etching step, and the barrier layer along the bottom has a bottom thickness ranging from 0 to about 150 Å after the sputter etching step.

5. The method of claim 2, wherein the barrier layer along the sidewalls has substantially uniform thickness after the sputter etching step.

6. The method of claim 1, wherein the sputter etching step includes bombarding select portions of the barrier layer with particles of an inert gas.

7. The method of claim 6, wherein the inert gas is argon.

8. The method of claim 7, wherein the source power for the inert gas sputter etching is about 100 watts to about 3000 watts, and the bias power for the inert gas sputter etching is about 100 watts to about 2000 watts.

9. A method of manufacturing a semiconductor device comprising the method of claim 1.

10. A method of forming a barrier layer in an opening, comprising:
forming a dielectric layer on a substrate;
forming an opening in the dielectric layer, the opening having sidewalls and a bottom;
depositing barrier layer material on the sidewalls and bottom of the opening; and
sputter etching to remove barrier layer material from the bottom of the opening and to redistribute barrier layer material removed from the bottom of the opening to the sidewalls.

11. The method of claim 10, wherein during the sputter etching step, the sputter etching also removes barrier layer material from an overhang portion of the barrier layer and redistributes barrier layer material removed from the overhang portion to the sidewalls.

12. The method of claim 10, wherein the sputter etching is performed until the barrier layer material is substantially removed from the bottom of the opening.

13. The method of claim 12, wherein the substrate is a dielectric layer having a conducting line therein, wherein the opening is a via opening to the conducting line, and further comprising:
depositing a conducting material into the opening to from a conductor-on-conductor interface at the bottom of the opening.

14. A method of manufacturing a semiconductor device comprising the method of claim 10.

15. A tunable process for redistributing portions of a barrier layer in an opening, comprising:
forming a dielectric layer on a substrate;
forming an opening in the dielectric layer, the opening having sidewalls and a bottom;
depositing barrier layer material on the sidewalls and bottom of the opening;
selecting at least one sputter process parameter for obtaining a desired barrier layer configuration;
sputter etching in accordance with the selected parameter(s) to redistribute portions of the barrier layer material and to provide the desired barrier layer configuration.

16. The tunable process of claim 15, wherein the selected parameter(s) include at least one of a sputtering time, a sputtering power, a sputtering source material, and a sputtering gas.

17. The tunable process of claim 15, wherein the selected parameter is a sputtering time.

18. The tunable process of claim 17, wherein the sputtering time ranges from about 2 seconds to about 24 seconds.

19. The tunable process of claim 15, wherein the selected parameter is a sputtering power.

20. The tunable process of claim 19, wherein the selected sputtering power parameter is a source power ranging from about 100 watts to about 3000 watts.

21. The tunable process of claim 19, wherein the selected sputtering power parameter is a bias power ranging from about 100 watts to about 2000 watts.

22. The tunable process of claim 15, wherein the selected parameter(s) being chosen to remove and redistribute barrier layer material from an overhang portion.

23. The tunable process of claim 15, wherein the selected parameter(s) being chosen to remove and redistribute barrier layer material from the bottom of the opening.

24. A method of forming an interconnect between layers for a semiconductor device, comprising:
forming an opening in one or more dielectric layers, wherein the opening opens to an underlying layer that is beneath the one or more dielectric layers;
depositing barrier layer material on interior surfaces of the opening to form a barrier layer;
sputter etching to remove barrier layer material from overhang portions of the barrier layer, to redistribute barrier layer material removed from the overhang portions to sidewalls of the opening, to remove barrier layer material from a bottom of the opening, and to redistribute barrier layer material removed from the bottom of the opening to the sidewalls, wherein the barrier layer is thicker along the sidewalls than along the bottom after the sputter etching step; and
depositing a conductive material into the opening.

25. The method of claim 24, wherein the sputter etching step includes bombarding select portions of the barrier layer with particles of an inert gas.

26. A method of manufacturing a semiconductor device comprising the method of claim 24.

27. A semiconductor device, comprising:
a first layer formed over an underlying layer;
an opening formed in the first layer and opening to the underlying layer;
a barrier layer formed within the opening, wherein the barrier layer is thicker along sidewalls of the opening than along a bottom of the opening; and
a conductive material formed on the barrier layer and within the opening.

28. The semiconductor device of claim 27, wherein the opening opens to a doped silicon region that is beneath the first layer.

29. The semiconductor device of claim 27, wherein the opening opens to a conductive material portion within the underlying layer.

30. The semiconductor device of claim 29, wherein the conductive material portion is a metal connecting line.

31. The semiconductor device of claim 30, wherein a substantial portion of the opening bottom has a barrier layer thickness of about zero, and wherein a metal contact is deposited in the opening to from a metal-on-metal interface at the opening bottom.

32. The semiconductor device of claim 27, wherein the barrier layer has a substantially uniform thickness along the sidewalls of the opening.

33. The semiconductor device of claim 27, wherein the barrier layer along the sidewalls has a sidewall thickness of about 50 Å, and the barrier layer along the bottom has a bottom thickness ranging from 0 to about 150 Å.

34. The semiconductor device of claim 27, wherein the first layer includes a dielectric material.

35. The semiconductor device of claim 34, wherein the first layer includes two dielectric layers.
